(19) United States
(12) Patent Application Publication
(10) Pub. No.: US 2024/0266419 A1
(43) Pub. Date: Aug. 8, 2024

(54) Semiconductor Device Having Semiconductor Structure with Polarity Inverting Layer

(71) Applicant: Wolfspeed, Inc., Durham, NC (US)

(72) Inventors: Matthew R. King, Wake Forest, NC (US); Kyle Bothe, Cary, NC (US); Christer Hallin, Hillsborough, NC (US)

(21) Appl. No.: 18/164,205

(22) Filed: Feb. 3, 2023

(51) Int. Cl. H01L 29/66; H01L 29/04; H01L 29/16; H01L 29/20; H01L 29/778

(52) U.S. Cl. CPC H01L 29/66462; H01L 29/045; H01L 29/1608; H01L 29/2003; H01L 29/7786

(57) ABSTRACT

Semiconductor devices are provided. In one example, a semiconductor device includes a substrate. The semiconductor device includes a polarity inverting layer on the substrate. The semiconductor device includes a nitrogen-polar (N-Polar) Group III-nitride semiconductor structure on the polarity inverting layer.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example embodiment of the present disclosure is directed to a semiconductor device. The semiconductor device includes a substrate. The semiconductor device includes a polarity inverting layer on the substrate. The semiconductor device includes a nitrogen-polar (N-Polar) Group III-nitride semiconductor structure on the polarity inverting layer.

Another example embodiment of the present disclosure is directed to a transistor device. The transistor device includes a silicon carbide substrate. The transistor device includes a transition metal nitride layer on the silicon carbide substrate. The transistor device includes an N-polar Group III-nitride semiconductor structure on the transition metal nitride layer. The N-polar Group III-nitride semiconductor structure includes a barrier layer and a channel layer on the barrier layer.

Another example embodiment of the present disclosure is directed to a method of forming an N-polar Group III-nitride semiconductor structure. The method includes depositing a polarity inverting layer on a silicon face of a silicon carbide substrate. The method includes epitaxially forming an N-polar Group III-nitride semiconductor structure on the polarity inverting layer.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts example metal-polar and nitrogen-polar (N-polar) Group-III nitride crystal structures.

FIG. 2 depicts an example semiconductor structure having a polarity inverting layer according to example embodiments of the present disclosure;

FIG. 3 depicts an example crystal structure of a polarity inverting layer according to example embodiments of the present disclosure;

FIG. 4 depicts an example crystal structure of a polarity inverting layer according to example embodiments of the present disclosure;

FIG. 5 depicts an example semiconductor structure having a polarity inverting layer according to example embodiments of the present disclosure;

FIG. 6 depicts an example semiconductor structure to be used in a transistor device according to example embodiments of the present disclosure;

FIG. 7 depicts an example semiconductor structure to be used in a transistor device according to example embodiments of the present disclosure;

FIG. 8 depicts an example transistor device having a semiconductor structure according to example embodiments of the present disclosure;

FIG. 9 depicts a flow chart of an example method according to example embodiments of the present disclosure;

FIG. 10 depicts example separation of an N-polar Group III-nitride semiconductor structure according to example embodiments of the present disclosure;

FIG. 11 depicts example placement of an N-Polar Group III-nitride semiconductor structure on a substrate according to example embodiments of the present disclosure;

FIG. 12 depicts a phase diagram of an example transition metal nitride that may be used as a polarity inverting layer according to example embodiments of the present disclosure;

FIG. 13 depicts a phase diagram of an example transition metal nitride that may be used as a polarity inverting layer according to example embodiments of the present disclosure;

FIG. 14 depicts a phase diagram of an example transition metal nitride that may be used as a polarity inverting layer according to example embodiments of the present disclosure;

FIG. 15 depicts a phase diagram of an example transition metal nitride that may be used as a polarity inverting layer according to example embodiments of the present disclosure;

FIG. 16 depicts a phase diagram of an example transition metal nitride that may be used as a polarity inverting layer according to example embodiments of the present disclosure;

FIG. 17 depicts a phase diagram of an example transition metal nitride that may be used as a polarity inverting layer according to example embodiments of the present disclosure;

FIG. 18 depicts a phase diagram of an example transition metal nitride that may be used as a polarity inverting layer according to example embodiments of the present disclosure; and

FIG. 19 depicts a phase diagram of an example transition metal nitride that may be used as a polarity inverting layer according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices, such as high electron mobility transistors (HEMTs), may be used in power electronics applications. HEMTs fabricated in Group III-nitride based material systems may have the potential to generate large amounts of radio frequency (RF) power because of the combination of material characteristics that includes high breakdown fields, wide band gaps, large conduction band offset, and/or high saturated electron drift velocity. As such, Group III-nitride based HEMTs may be promising candidates for high frequency and/or high-power RF applications (as well as for low frequency high power switching applications) as discrete transistors or as coupled with other circuit elements, such as in monolithic microwave integrated circuit (MMIC) devices.

Field effect transistors such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different band gap energies, where the smaller band gap material has a higher electron affinity. The 2DEG is an accumulation layer in the smaller band gap material and may include a very high sheet electron concentration. Additionally, electrons that originate in the wider-band gap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

HEMT devices may include metal-polar (e.g., Ga-polar) or nitrogen-polar (e.g., N-polar) Group III-nitride semiconductor structures. More specifically, Group III-nitride semiconductor structures may have a hexagonal wurtzite crystal structure that lacks inversion symmetry along a c-plane of the crystal structure. The lack of inversion symmetry may result in polarization effects. The polarization effects may lead to, for instance, a spontaneous polarization dipole in the Group III-nitride semiconductor structure. A direction associated with the spontaneous polarization dipole may determine whether the Group III-nitride semiconductor structure is metal-polar or N-polar.

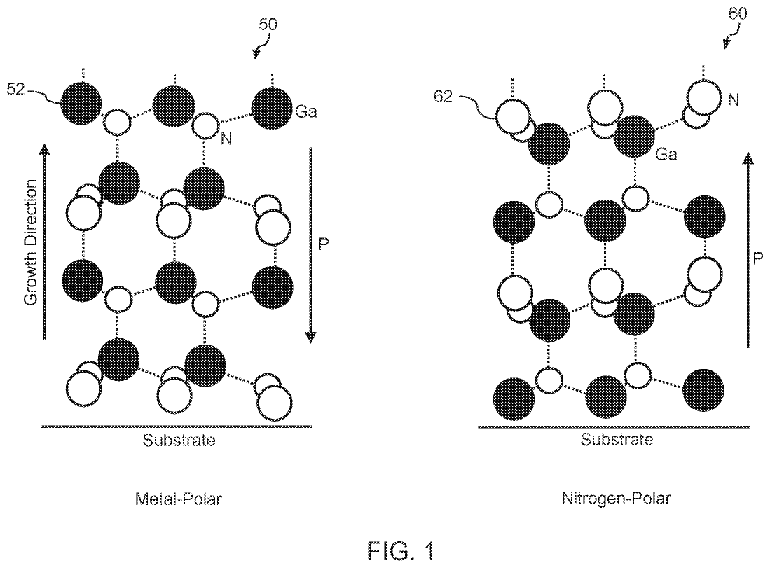

For instance, FIG. 1 depicts an example metal-polar Group III nitride semiconductor structure 50 (e.g., Ga-polar GaN) and an example N-polar Group III-nitride semiconductor structure 60 (e.g., N-polar GaN). As shown, the metal-polar Group III-nitride semiconductor structure 50 and the N-polar Group III-nitride semiconductor structure 60 each have a hexagonal wurtzite crystal structure. In a wurtzite crystal structure, the metal (e.g., gallium) and the nitrogen are arranged in separate distinct layers. The metal-polar (e.g., Ga-polar) Group III-nitride semiconductor structure 50 has a metal face 52 (e.g., gallium face) in the growth direction of the semiconductor structure 50 relative to a substrate. The direction of the spontaneous polarization dipole P may be opposite the growth direction in the metal-polar Group III-nitride semiconductor structure 50. The N-polar semiconductor structure 60 has a nitrogen face 62 in the growth direction of the semiconductor structure 60 relative to a substrate. The direction of the spontaneous polarization dipole P may be the same as the growth direction in the N-polar Group III-nitride semiconductor structure 60.

HEMT devices including N-polar Group III-nitride structures have recently been shown to deliver significant performance advantages, particularly at operating frequencies in the mm wave frequency ranges (e.g., 30 GHz or greater) relative to traditional metal polar Group-III nitride structures. Formation of N-polar group III-nitride semiconductor structures may pose challenges. N-polar group III-nitride semiconductor structures have been epitaxially grown on sapphire substrates. However, the use of sapphire substrates may be undesirable for certain high frequency, high power RF applications due to intrinsic properties of sapphire, such as low thermal conductivity relative to, for instance, silicon carbide (SiC) substrates.

N-polar group III-nitride semiconductor structures have been grown on a carbon-face (C-face) of SiC substrates. This may require the use of special, less available C-face SiC substrates. Moreover, epitaxial growth of semiconductor structures on a C-face is less stable than epitaxial growth on the silicon-face (Si-face) of SiC substrates.

Example aspects of the present disclosure provide for the use of a polarity inverting layer on a substrate as a seed layer for formation of N-polar Group-III nitride semiconductor structures. The substrate may be, for instance, a SiC substrate. The polarity inverting layer may induce a polarity inversion (e.g., an inversion of the spontaneous dipole moment) of the Group III-nitride semiconductor structure formed on the substrate. The polarity inverting layer may allow for formation (e.g., epitaxial growth) of the N-polar Group III-nitride semiconductor structure on the Si-face of the silicon carbide substrate.

In some embodiments, the polarity inverting layer may be a transition metal nitride. The transition metal nitride may have composition, phase, and/or crystal structure to trigger polarity inversion of the Group III-nitride semiconductor structure formed on the transition metal nitride. For instance, the transition metal nitride may have a face centered cubic (FCC) crystal structure or a hexagonal close packed (HCP) crystal structure. The crystal structure may have certain parameters (e.g., lattice parameter, FCC plane distance, lattice mismatch relative to silicon carbide, lattice mismatch relative to Group III-nitride) to foster polarity inversion in a Group III-nitride semiconductor structure formed on the transition metal nitride and may be suitable in process conditions required for formation of the Group III-nitride semiconductor structure. For instance, in some examples, the transition metal nitride may not exhibit a phase transition at temperatures for growth of Group III-nitride semiconductor structures. In some examples, the transition metal nitride may be, for instance, niobium nitride (NbₓN_{y}), titanium nitride (TiₓN_{y}), zirconium nitride (ZrₓN_{y}), hafnium nitride (HfₓN_{y}), vanadium nitride (VₓN_{y}), tantalum nitride (TaₓN_{y}), chromium nitride (CrₓN_{y}), molybdenum nitride (MoₓN_{y}), or tungsten nitride (WₓN_{y}).

Examples of the present disclosure provide technical effects and benefits. For instance, use of a polarity inverting layer, such as a transition metal nitride layer, may provide for the growth of N-polar Group III-nitride semiconductor structures using industry standard, readily available Si-face silicon carbide substrates, rather than the more challenging and less available C-face silicon carbide substrates. Forming N-polar Group III-nitride structures in this way provides for the use of N-polar Group III-nitride semiconductor structures in semiconductor devices, such as HEMTs, for a wide variety of applications, including high frequency, and/or high-power RF applications (e.g., greater than about 30 GHz). In this way, examples of the present disclosure may provide access to high power and/or high frequency RF performance associated with N-polar Group III-nitride semiconductor structures, while leveraging the existing economy of scale for Si-face SiC substrates.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other semiconductor devices without deviating from the scope of the present disclosure, such as Schottky rectifiers.

In the drawings and specification, there have been disclosed typical embodiments and, although specific terms are employed, they are used in a generic and descriptive sense only and not for purposes of limitation of the scope set forth in the following claims. With reference now to the Figures, example embodiments of the present disclosure will now be set forth.

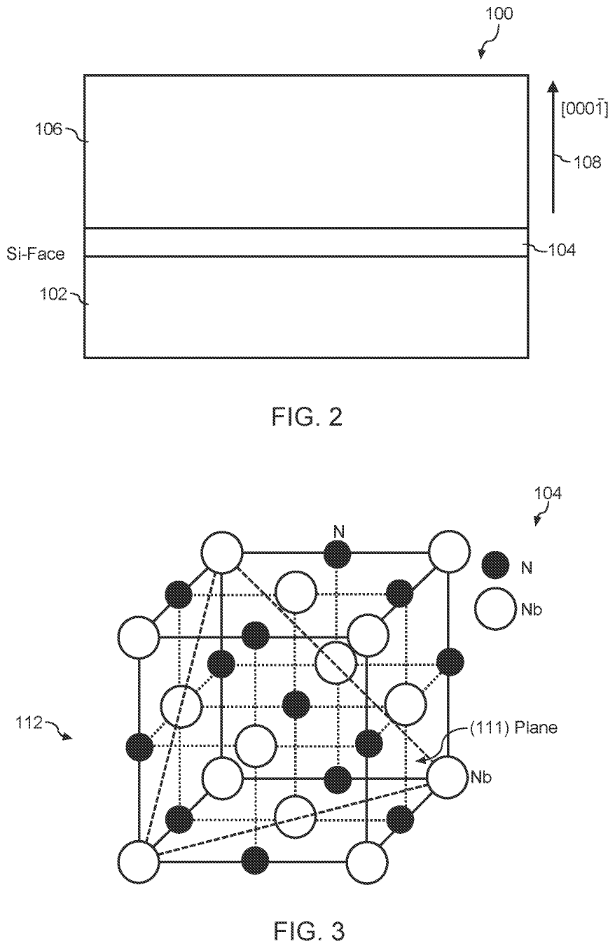

FIG. 2 depicts an example semiconductor structure 100 according to example embodiments of the present disclosure. FIG. 2 is intended to represent structures for identification and description and is not intended to represent the structures to physical scale. The semiconductor structure 100 includes a substrate 102, a polarity inverting layer 104 on the substrate 102, and a Group III-nitride semiconductor structure 106 on the polarity inverting layer 104. The polarity inverting layer 104 may induce polarity inversion (e.g., an inversion of the spontaneous dipole moment) of the Group III-nitride semiconductor structure 106 formed on the substrate such that the Group III-nitride semiconductor structure 106 is an N-polar Group III-nitride semiconductor structure as indicated by a growth direction 108 toward the [0001̅] direction of the Group III-nitride semiconductor structure 106 in FIG. 2.

The substrate 102 may be a semiconductor material. For instance, the substrate 102 may be a silicon substrate, a silicon carbide (SiC) substrate, a sapphire substrate, or other suitable substrate. In some embodiments, the substrate 102 may be a semi-insulating SiC substrate that may be, for example, the 4H polytype of SiC or may be the 3C, 6H, and 15R polytypes of SiC. The substrate 102 may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 102 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material in some examples, other examples of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. In some examples, the substrate 102 may have a thickness in a range of, for instance, about 50 μm to about 300 μm, such as in range of about 75 μm to about 200 μm, such as about 100 μm.

According to example aspects of the present disclosure, a polarity inverting layer 104 is formed on a silicon face of a SiC substrate 102. The polarity inverting layer 104 may induce a polarity inversion in the Group III-nitride semiconductor structure 106 during formation of the Group III-nitride semiconductor structure. The polarity inverting layer 104 may be a transition metal nitride layer. For instance, the polarity inverting layer 104 may be niobium nitride (NbₓN_{y}), titanium nitride (TiₓN_{y}), zirconium nitride (ZrₓN_{y}), hafnium nitride (HfₓN_{y}), vanadium nitride (VₓN_{y}), tantalum nitride (TaₓN_{y}), chromium nitride (CrₓN_{y}), molybdenum nitride (MoₓN_{y}), or tungsten nitride (WₓN_{y}).

As will be described in more detail below, the polarity inverting layer 104 may have properties to induce the polarity inversion and may be suitable for formation of the N-polar Group III-nitride structure 106. The polarity inverting layer 104 may be formed on the substrate using a deposition process, such a chemical vapor deposition (CVD), physical vapor deposition (PVD), sputter deposition, atomic layer deposition (ALD), or other suitable deposition process. The polarity inverting layer 104 may have a thickness in a range of about 5 nm to about 100 nm, such as about 10 nm to about 75 nm.

The Group III-nitride semiconductor structure 106 may be formed on the polarity inverting layer 104 using, for instance, metal-organic chemical vapor deposition (MOCVD), molecular beam epitaxy (MBE), or hydride vapor phase epitaxy (HVPE). Techniques for epitaxial growth of Group III-nitrides have been described in, for example, U.S. Pat. Nos. 5,210,051, 5,393,993, and 5,523,589, the disclosures of which are incorporated by reference herein.

The Group III-nitride semiconductor structure 106 may be a single layer structure or a multilayer structure. In the multilayer structure, each layer of the Group III-nitride semiconductor structure may be a different Group III-nitride compound. As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements.

The Group III-nitride semiconductor structure 106 is N-polar as indicated by the growth direction 108 toward the direction. In this way, an N-polar Group III-nitride semiconductor structure 106 may be formed, for instance, on a Si-face of a SiC substrate 102.

The polarity inverting layer 104 may have composition, phase, crystal structure and/or other characteristics to trigger polarity inversion and suitable formation of the Group III-nitride semiconductor structure 106 on the polarity inverting layer 104. The polarity inverting layer 104 may also have properties that are suitable for temperatures and other process conditions during formation (e.g., epitaxial growth) of the Group III-nitride semiconductor structure 106.

For instance, the polarity inverting layer 104 may have a close lattice match to materials in the semiconductor structure 100 (e.g., SiC, AlN, GaN) to reduce strain and limit formation of dislocations. In some examples, the polarity inverting layer 104 has a crystal structure that has a good match or has an available abstraction to provide a good match with the wurtzite crystal structure of Group III-nitride semiconductor structure 106.

For instance, in some examples, the polarity inverting layer 104 may have a face centered cubic (FCC) crystal structure. FIG. 3 depicts an example FCC crystal structure 112 for a transition metal nitride (e.g., NbₓN_{y}) acting as a polarity inverting layer 104 according to example embodiments of the present disclosure. A (111) plane of the FCC crystal structure 112 may provide a good match with the wurtzite crystal structure of an N-polar Group III-nitride semiconductor structure 106.

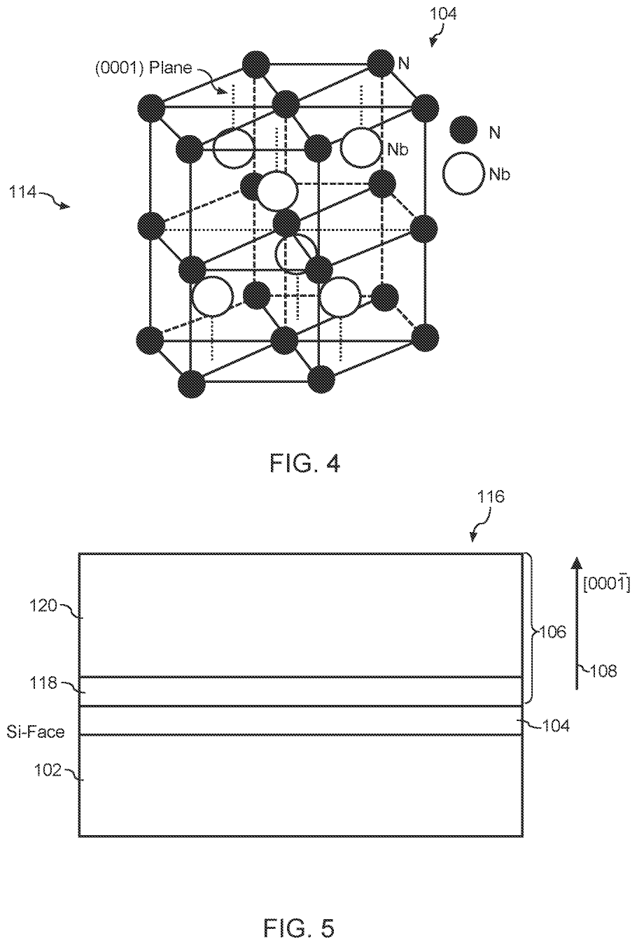

In some examples, the polarity inverting layer 104 may have a hexagonal close packed (HCP) crystal structure. FIG. 4 depicts an example HCP crystal structure 114 for a transition metal nitride (e.g., NbₓN_{y}) acting as a polarity inverting layer 104 according to example embodiments of the present disclosure. The HCP crystal structure 114 may have alternating planes of a metal nitride (e.g., Nb) and nitrogen arranged in distinct layers. A (0001) plane of the HCP crystal structure 114 may provide a good match with the wurtzite crystal structure of an N-polar Group III-nitride semiconductor structure.

In some embodiments, the polarity inverting layer 104 may have a crystal structure (e.g., HCP crystal structure or an FCC crystal structure) with lattice characteristics (e.g., lattice parameters, FCC plane distance, mismatch to 4H—SiC, mismatch to AlN, mismatch to GaN) to provide a good match with the substrate 102 and/or the N-polar Group III-nitride semiconductor structure 106.

For instance, the polarity inverting layer 104 may have an FCC crystal structure with a lattice parameter in a range of about 3.5 Angstroms to about 5 Angstroms, such as about 4 Angstroms to about 5 Angstroms. The polarity inverting layer 104 may have an FCC plane distance in a range of about 2.5 Angstroms to about 3.5 Angstroms, such as about 3 Angstroms to about 3.5 Angstroms. The polarity inverting layer 104 may have a crystal structure with a percentage lattice mismatch to 4H-SiC of about −6.0% to about 6.0%. The polarity inverting layer 104 may have a crystal structure with a percentage lattice mismatch to gallium nitride (GaN) of about −10.0% to about 2.0%. The polarity inverting layer 104 may have a crystal structure with a percentage lattice mismatch to aluminum nitride (AlN) of about −7.0% to about 5.0%.

Table 1 below provides example lattice characteristics of transition metal nitrides that can be a polarity inverting layer 104 according to examples of the present disclosure.

TABLE 1

| Transition | | FCC Plane Distance (nm) |
|---|---|---|
| Metal Nitride | Lattice Parameter (nm) | (between (111) planes) |
| NbₓN_{y} | 0.4392 | 0.3106 |
| TiₓN_{y} | 0.4242 | 0.3000 |
| ZrₓN_{y} | 0.457 | 0.3231 |
| HfₓN_{y} | 0.4516 | 0.3193 |
| VₓN_{y} | 0.4138 | 0.2926 |
| TaₓN_{y} | 0.4238 | 0.2997 |
| CrₓN_{y} | 0.4148 | 0.2933 |
| MoₓN_{y} | 0.4162 | 0.2943 |
| WₓN_{y} | 0.4118 | 0.2912 |

Table 2 below provides example lattice characteristics of transition metal nitrides that can be a polarity inverting layer 104 according to examples of the present disclosure.

TABLE 2

| Transition | % Mismatch | % Mismatch | % Mismatch |
|---|---|---|---|
| Metal Nitride | to 4H—SIC | to AlN | to GaN |
| NbₓN_{y} | 1.06% | −0.21% | −2.68% |
| TiₓN_{y} | −2.39% | −3.61% | −6.00% |
| ZrₓN_{y} | 5.16% | 3.84% | 1.27% |
| HfₓN_{y} | 3.91% | 2.61% | 0.07% |
| VₓN_{y} | −4.78% | −5.98% | −8.30% |
| TaₓN_{y} | −2.48% | −3.70% | −6.09% |
| CrₓN_{y} | −4.55% | −5.75% | −8.08% |
| MoₓN_{y} | −4.23% | −5.43% | −7.77% |
| WₓN_{y} | −5.24% | −6.43% | −8.75% |

In some examples, the polarity inverting layer 104 may include a transition metal nitride that has a phase stability in a temperature range associated with formation (e.g., epitaxial growth) of the Group III-nitride structure 106 so that there is no phase transition or decomposition of the transition metal nitride in the temperature range associated with process conditions for the formation (e.g., epitaxial growth) of the Group III-nitride structure 106. For instance, the polarity inverting layer 104 may not exhibit a phase transition or any decomposition at temperatures up to about 1300° C., such as in a range of up to about 900° C. to about 1300° C.

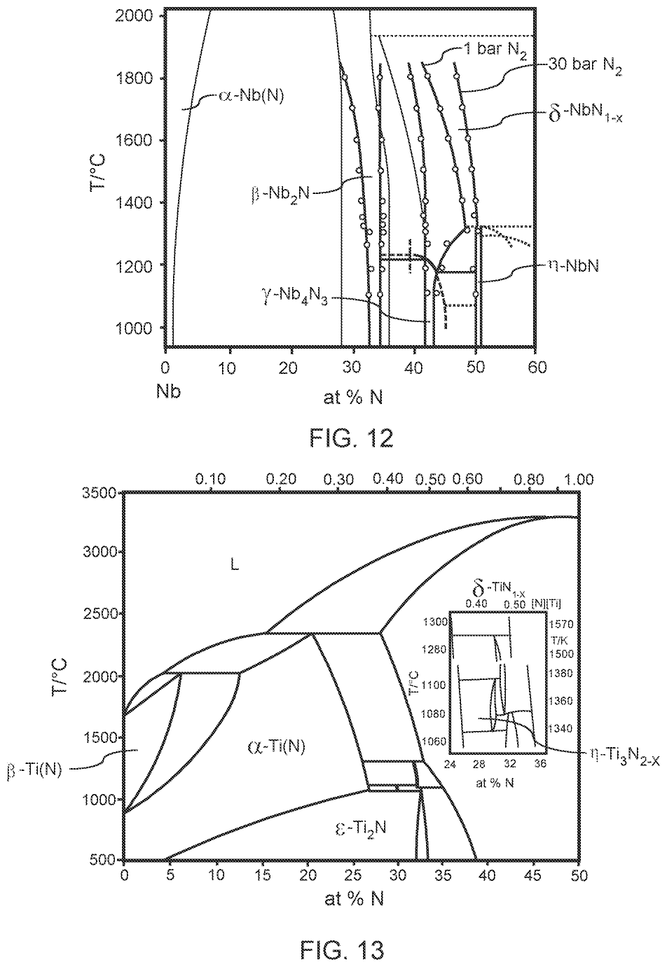

FIGS. 12-19 depict example phase diagrams of transition metal nitrides that may be used as polarity inverting layers according to example embodiments of the present disclosure. Each of phase diagram of FIGS. 12-19 depicts % N in the transition metal nitride on the horizontal axis and temperature along the vertical axis. The plots represent boundaries between different phases of the transition metal nitride at different temperatures and different compositions.

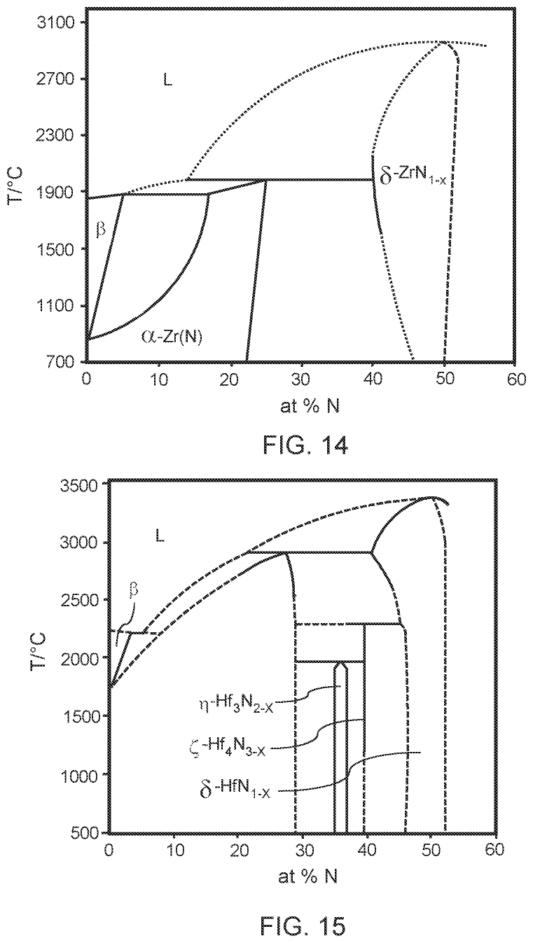

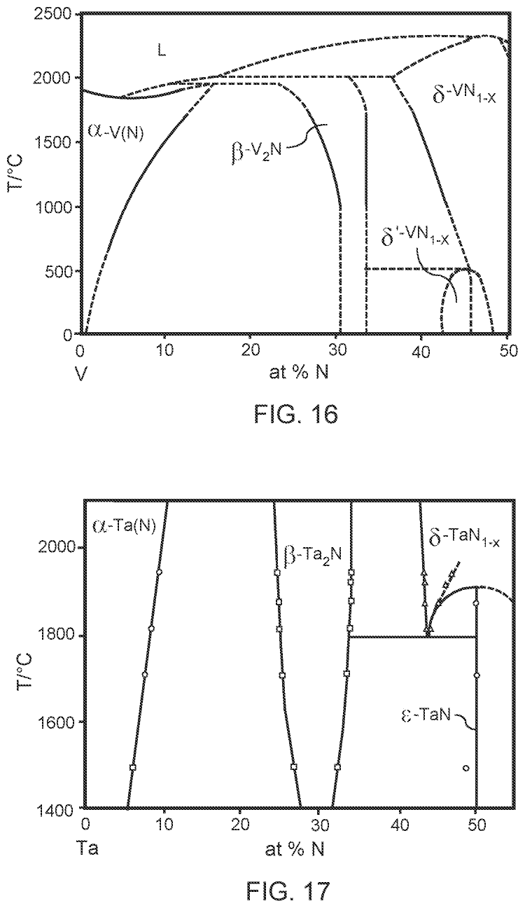

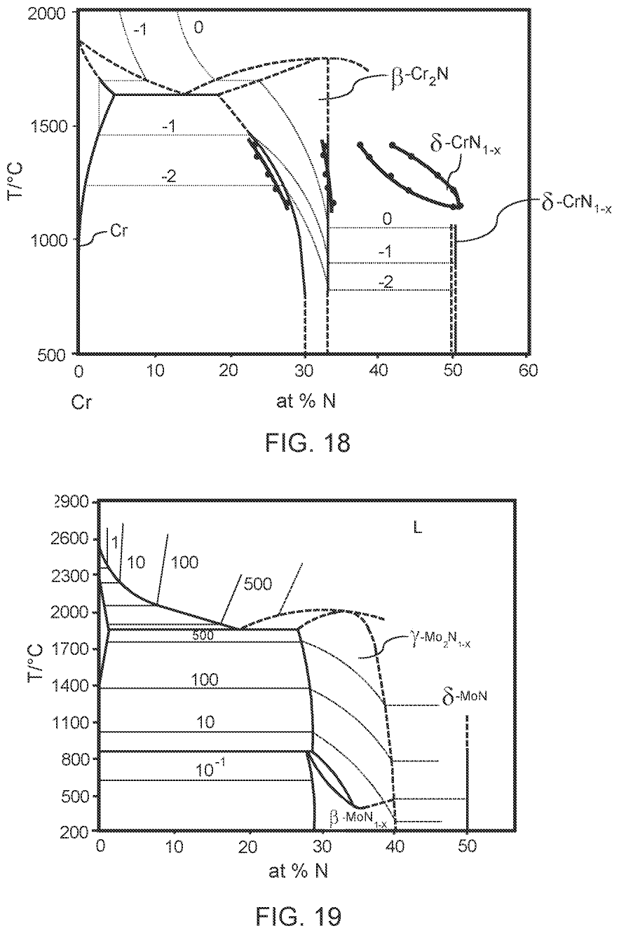

More particularly, FIG. 12 depicts a phase diagram for niobium nitride (NbₓN_{y}). FIG. 13 depicts a phase diagram for titanium nitride (TiₓN_{y}), FIG. 14 depicts a phase diagram for zirconium nitride (ZrₓN_{y}). FIG. 15 depicts a phase diagram for hafnium nitride (HfₓN_{y}). FIG. 16 depicts a phase diagram for vanadium nitride (VₓN_{y}). FIG. 17 depicts a phase diagram for tantalum nitride (TaₓN_{y}). FIG. 18 depicts a phase diagram for chromium nitride (CrₓN_{y}). FIG. 19 depicts a phase diagram for molybdenum nitride (MoₓN_{y}). As demonstrated by FIGS. 12-19, various compositions of the metal nitrides may exhibit no phase transitions in temperature ranges of up to about 900° C. to about 1300° C.

In some embodiments, the polarity inverting layer 104 may have a sticking coefficient for adsorbate atoms associated with the Group III-nitride semiconductor structure 106 (e.g., aluminum and/or gallium) at temperatures and process conditions associated with formation (e.g., epitaxial growth) of the Group III-nitride semiconductor structure 106 on the polarity inverting layer 104. For instance, the polarity inverting layer 104 may have a sticking coefficient of about 0.3 or greater for adsorbate aluminum and adsorbate gallium at temperatures up to about 1300° C., such as in a range of about 900° C. to about 1300° C.

A variety of different N-polar Group III-nitride semiconductor structures may be formed on the polarity inverting layer 104 without deviating from the scope of the present disclosure. For instance, FIG. 5 depicts a semiconductor structure 116 having a multilayer Group III-nitride semiconductor structure 106 on a polarity inverting layer 104 on a substrate 102 according to example embodiments of the present disclosure. FIG. 5 is intended to represent structures for identification and description and is not intended to represent the structures to physical scale. The Group III-nitride semiconductor structure 106 of FIG. 5 is N-polar as indicated by the growth direction 108 toward the direction. The semiconductor structure 116 is similar to that of the semiconductor structure 100 of FIG. 2, except that the N-polar Group III-nitride semiconductor structure 106 has a first layer 118 and a second layer 120.

The first layer 118 may be a nucleation layer for the Group III-nitride semiconductor structure 106. The nucleation layer may be, for instance, a gallium nitride (GaN) layer and/or an aluminum nitride (AlN) layer to provide a crystal structure transition between, for instance, the substrate 102, the polarity inverting layer 104 and/or the Group III-nitride semiconductor structure 106. In some examples, the first layer may be an N-polar Group III nitride, such as AlᵤGa₁₋ᵤN, where 0.5≤u≤1. In some examples, the aluminum mole fraction u is approximately 1, indicating that the first layer 118 is AlN. The first layer 118 may or may not include other Group III-nitrides such as InGaN, AlInGaN or the like. The first layer 118 may be undoped. The first layer 118 may have a thickness in the range of about 50 Angstroms to about 1000 Angstroms, such as about 100 Angstroms.

The second layer 120 may be a buffer layer for the Group III-nitride semiconductor structure 106. The second layer 120 may be an N-polar Group III nitride, such as AlᵥGa₁₋ᵥN, where 0≤v<0.1. In some embodiments, the aluminum mole fraction v is approximately 0 (e.g., 0.05 or less), indicating that the second layer 120 is GaN. The second layer 120 may or may not include other Group III-nitrides such as InGaN, AlInGaN or the like. The second layer 120 may be undoped. The second layer 120 may have a thickness in the range of about 0.5 μm to about 5 μm, such as about 2 μm. The second layer 120 may be a multi-layer structure, such as a superlattice or combinations of GaN, AlGaN or the like. The second layer 120 may be under compressive strain in some embodiments.

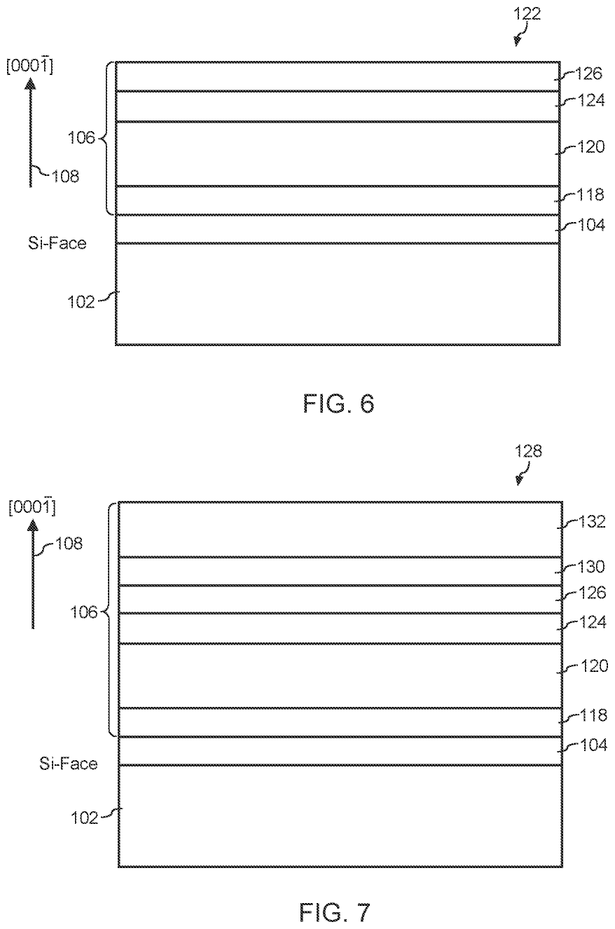

FIGS. 6 and 7 depict example semiconductor structures that may be used, for instance, in a high electron mobility transistor device, according to example embodiments of the present disclosure. FIGS. 6 and 7 are intended to represent structures for identification and description and are not intended to represent the structures to physical scale.

FIG. 6 depicts a semiconductor structure 122 having a multilayer Group III-nitride semiconductor structure 106 on a polarity inverting layer 104 on a substrate 102 according to example embodiments of the present disclosure. The Group III-nitride semiconductor structure 106 of FIG. 6 is N-polar as indicated by the growth direction 108 toward the direction. The semiconductor structure 122 is similar to that of the semiconductor structure 116 of FIG. 5 except that the N-polar Group III-nitride semiconductor structure additionally has a barrier layer 124 (e.g., a back barrier layer) and a channel layer 126.

The barrier layer 124 may be on the second layer 120 (e.g., buffer layer). The barrier layer 124 may be an N-polar Group III nitride, such as Al_{w}Ga_{1-w}N where 0.1≤w<0.4, indicating that the barrier layer 124 is an AlGaN layer. The barrier layer 124 may or may not include other Group III-nitrides such as InGaN, AlInGaN or the like. The barrier layer 124 may have a different band gap relative to the channel layer 126. The barrier layer 124 may have a thickness in a range of about 250 Angstroms to about 350 Angstroms, such as about 300 Angstroms.

In some embodiments, the barrier layer 124 may be a multilayer structure. For instance, in one example, the barrier layer 124 may include a first layer of n+ doped GaN with a thickness of about 100 Angstroms. The barrier layer 124 may include a second layer of graded Al_{w.1}Ga_{1-w.1}N on the first layer, where w.1 varies from about 0.05 to about 0.4. The second layer of graded Al_{w}Ga_{1-w}N may have a thickness of about 100 Angstroms. The barrier layer 124 may include a third layer of Al_{w.2}Ga_{1-w.2}N on the second layer, where w.2 is in a range of 0.3 to 0.4. The thickness of the third layer may be about 100 Angstroms. The barrier layer 124 may include a fourth layer of AlN on the third layer. The thickness of the fourth layer may be in a range of about 5 Angstroms to about 15 Angstroms, such as about 7 Angstroms.

The channel layer 126 may be on the barrier layer 124. The barrier layer 124 may be an N-polar Group III-nitride, such as AlₓGa₁₋ₓN, where 0≤x<0.1, provided that the energy of the conduction band edge of the channel layer 126 is less than the energy of the conduction band edge of the barrier layer 124 at the interface between the channel layer 126 and the barrier layer 124. The channel layer 126 may have a band gap that is different than the band gap of the barrier layer 124. In some embodiments, the aluminum mole fraction x is approximately 0 (e.g., 0.05 or less), indicating that the channel layer 126 is GaN. The channel layer 126 may or may not include other Group III-nitrides such as InGaN, AlInGaN or the like. The channel layer 126 may have a thickness in a range of about 75 Angstroms to about 125 Angstroms, such as about 100 Angstroms.

FIG. 7 depicts a semiconductor structure 128 having a multilayer Group III-nitride semiconductor structure 106 on a polarity inverting layer 104 on a substrate 102 according to example embodiments of the present disclosure. The Group III-nitride semiconductor structure 106 of FIG. 7 is N-polar as indicated by the growth direction 108 toward the direction. The semiconductor structure 128 is similar to that of the semiconductor structure 122 of FIG. 6 except that the N-polar Group III-nitride semiconductor structure additionally has a first cap layer 130 and a second cap layer 132.

The first cap layer 130 may be on the channel layer 126. The first cap layer 130 may be an N-polar Group III-nitride, such as Al_{y}Ga_{1-y}N where 0.1≤y<0.4, indicating that the first cap layer 130 is an AlGaN layer. In some embodiments, the aluminum mole fraction y is in a range of about 0.2 to about 0.3. The first cap layer 130 may or may not include other Group III-nitrides such as InGaN, AlInGaN or the like. The first cap layer 130 may have a band gap that is different than the band gap of the channel layer 126. The first cap layer 130 may have a thickness in a range of about 15 Angstroms to about 50 Angstroms, such as about 26 Angstroms.

A second cap layer 132 may be on the first cap layer 130. The second cap layer 132 may be an N-polar Group III-nitride, such as Al_{z}Ga_{1-z}N, where 0≤z<0.1. In some embodiments, the aluminum mole fraction z is approximately 0 (e.g., 0.05 or less), indicating that the second cap layer is a GaN layer. The cap layer 132 may or may not include other Group III-nitrides such as InGaN, AlInGaN or the like. The cap layer 132 buries the channel layer 126 deep below the surface of semiconductor structure 128 such that the channel layer 126 is a buried layer at a depth of about 275 Angstroms or greater from the surface of the semiconductor structure 128, such as about 500 Angstroms or greater from the surface of the semiconductor structure 128, such as in a range of about 275 Angstroms to about 1000 Angstroms from the surface of the semiconductor structure 128. The second cap layer 132 may have a thickness in a range of about 250 Angstroms to about 1000 Angstroms, such as about 500 Angstroms.

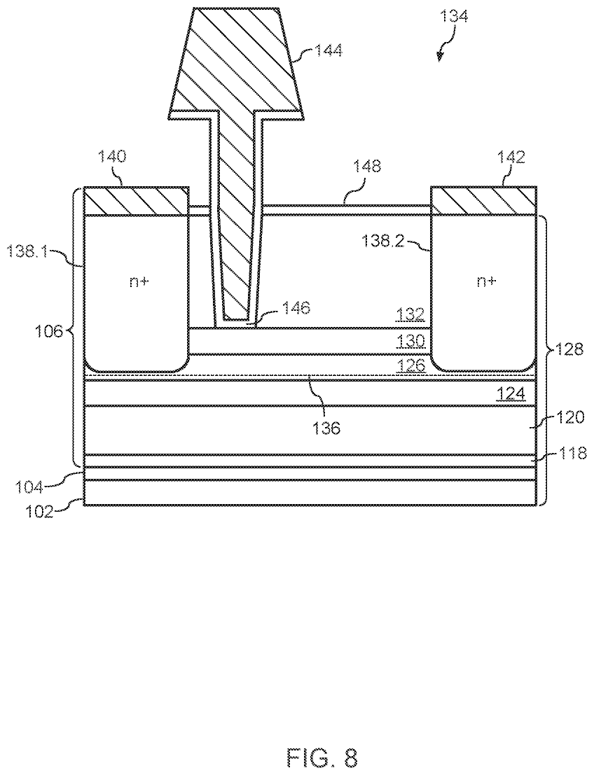

FIG. 8 depicts a cross-sectional view of an example high electron mobility transistor (HEMT) device 134 according to example embodiments of the present disclosure. FIG. 8 is intended to represent structures for identification and description and is not intended to represent the structures to physical scale. The HEMT device 134 may include a semiconductor structure 128 (e.g., as illustrated in FIG. 7) that includes an N-polar Group III-nitride semiconductor structure 106 on a polarity inverting layer 104 on a substrate 102 as described with reference to FIGS. 2 and 5-7. For instance, the N-polar Group III-nitride semiconductor structure may include a nucleation layer 118, a buffer layer 120, a barrier layer 124, a channel layer 126, a first cap layer 130, and a second cap layer 132.

A 2DEG 136 may be induced in the channel layer 126 at the interface between the channel layer 126 and the barrier layer 124. The 2DEG 136 is highly conductive and allows conduction between the source and drain regions of the HEMT device 134. The 2DEG 136 may be controlled under operation of a gate, such that the HEMT device 134 acts as a controllable transistor device.

The semiconductor structure 128 includes implanted regions 138.1 and 138.2. The implanted regions 138.1 and 138.2 may include a distribution of implanted dopants (e.g., ions) of a first conductivity type such that the implanted regions 138.1 and 138.2 are n-type regions. The implanted regions 138.1 and 138.2 may extend through the semiconductor structure 128 and into the channel layer 126.

The implanted regions 138.1 and 138.2 may include a distribution of implanted dopants extending into the channel layer 126. The implanted dopants may be of a first conductivity type such that the implanted regions 138.1 and 138.2 are each an n-type region. The implanted dopants may be, for instance, silicon, germanium, sulfur, and/or oxygen ions.

The implanted regions 138.1 and 138.2 may each have a distribution of implanted dopants that extends to a depth from the surface of the semiconductor structure 128. The depth may be about 275 Angstroms or greater, such as about 500 Angstroms or greater, such as in a range of about 275 Angstroms to about 1000 Angstroms. The distribution of implanted dopants may extend through the second cap layer 132, the first cap layer 130 and to the channel layer 126. In some embodiments, the distribution of implanted dopants may extend into the barrier layer 124 and/or into the buffer layer 120 of the semiconductor structure 128.

The implanted regions 138.1 and 138.2 may each have a peak dopant concentration of 1×10¹⁸ ions/cm³ or greater. For example, in some embodiments, the dose and energy of the implants may be selected to provide a peak dopant concentration of about 5×10²⁰ ions/cm³ in the implanted regions 138.1 and 138.2. The distribution of implanted dopants in the implanted regions 138.1 and 138.2 may have its peak dopant concentration at a depth in the implanted regions 138.1 and 138.2 close to channel layer 126 of the semiconductor structure 128. For instance, the peak dopant concentration may be in a region within the implanted regions 138.1 and 138.2. The region may be within 50 Angstroms or less of the channel layer 126. In some examples, the region may be within the buried channel layer 126. In some examples, the distribution of implanted dopants may provide a substantially uniform concentration of implanted dopants throughout the implanted regions 138.1 and 138.2 of the semiconductor structure 128.

The HEMT device 134 includes electrodes on the implanted regions 138.1 and 138.2. More particularly, the HEMT device 134 may include a source contact 140 on the implanted region 138.1. The HEMT device 134 may include a drain contact 142 on the implanted region 138.2. The electrodes may form an ohmic contact with the respective implanted regions 138.1 and 138.2. The implanted dopants within implanted region 138.1 may provide a low resistive path between the ohmic source contact 140 and the channel layer 126. For instance, the implanted region 138.1 may have a dopant concentration such that the implanted region 138.1 has a resistivity in a range of about 0.2 Ohms-mm or less. The implanted dopants within implanted region 138.2 may provide a low resistive path between the ohmic drain contact 142 and the channel layer 126. For instance, the implanted region 138.2 may have a dopant concentration such that the implanted region 138.2 has a resistivity in a range of about 0.2 Ohms-mm or less.

The source contact 140 and the drain contact 142 may be laterally spaced apart from each other. In some embodiments, the source contact 140 and the drain contact 142 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 140 may be an ohmic contact. The drain contact 142 may be an ohmic contact. In some embodiments, the source contact 140 and/or the drain contact 142 may include a plurality of layers to form an ohmic contact that may be provided as described, for example, in U.S. Pat. Nos. 8,563,372 and 9,214,352, the disclosures of which are incorporated by reference herein.

The HEMT device 134 may include a gate contact 144. The gate contact 144 may extend at least partially through a trench (e.g., an ALE defined trench) in the second cap layer 132 so that the gate contact 144 is proximate to the first cap layer 130. In some examples, the gate contact 144 may have a gate length in a range of about 50 nm to about 150 nm. The gate length is the length of the gate contact 144 along the surface proximate the first cap layer 130.

A passivation layer 146 may be located between the gate contact 144 and the first cap layer 130. The passivation layer 146 may be SiN. Other suitable dielectric layers may be used as the passivation layer 146, such as SiO₂, MgOx, MgNx, ZnO, SiNx, SiOx or other dielectric layers. The passivation layer 146 may be formed, for instance, using MOCVD process(s), atomic layer deposition (ALD) process(s), and/or sputter deposition processes. The passivation layer 146 may serve as a gate dielectric. In some examples, the passivation layer 146 may have a thickness, for instance, of about 5 Angstroms to about 100 Angstroms, such as about 10 Angstroms to about 50 Angstroms.

The gate contact 144 may be a T-shaped gate or a gamma gate, the formation of which is discussed by way of example in U.S. Pat. Nos. 8,049,252, 7,045,404, and 8,120,064, the disclosures of which are incorporated by reference herein. The material of the gate contact 144 may be chosen based on the composition of the first cap layer 130. Materials capable of making a contact to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

The HEMT device 134 may include additional passivation layer(s) 148 on the semiconductor structure 128, the gate contact 144, and/or other structures of the HEMT device 134. The additional passivation layer(s) 148 may be, for instance, dielectric materials, such as SiO₂, MgOx, MgNx, ZnO, SiNx, SiOx, alloys or layer sequences thereof. The additional passivation layer(s) 148 may be formed using MOCVD process(s), ALD process(s), sputter deposition process(s), or other suitable process(s). One or more insulating layers (not shown) may be on the HEMT device 134. For instance, the HEMT device 134 may be encapsulated in an insulating material without deviating from the scope of the present disclosure.

A transistor may be formed by the active region between the source contact 140 and the drain contact 142 under the control of a gate contact 144 between the source contact 140 and the drain contact 142. FIG. 8 depicts a cross-sectional view of one unit of an HEMT device 134 for purposes of illustration. The HEMT device 134 may be formed adjacent to additional HEMT device units and may share, for instance, a source contact 140 with adjacent HEMT device units.

In some examples, the HEMT device 134 may be operable at frequencies of up to about 150 GHz. For instance, the HEMT device 134 may be operable at a frequency in a range of about 10 GHz to about 150 GHz, such as in a range of about 30 GHz to about 150 GHz, such as in a range of about 50 GHz to about 150 GHz. In some examples, the HEMT device 134 may have a power density of up to 10 W/mm or greater in these frequency ranges, such as a power density in a range of 2.5 W/mm to about 12 W/mm.

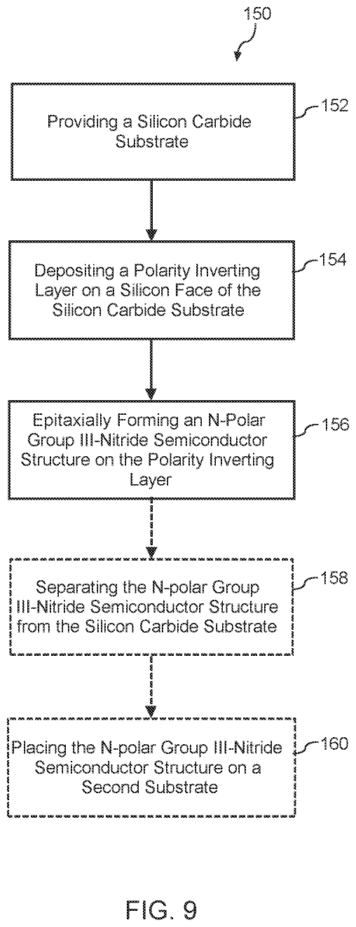

FIG. 9 depicts a flow chart of an example method 150 for fabricating a semiconductor device according to example embodiments of the present disclosure. FIG. 9 depicts example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 152, the method 150 may include providing a substrate, such as a silicon carbide substrate. The substrate may be, for instance, the substrate 102 described with reference to FIGS. 2 and 5-7. In some examples, the substrate may be a SiC substrate with an Si-face and a C-face.

At 154, the method 150 may include depositing a polarity inverting layer on the substrate. The polarity inverting layer may be formed on the Si-face of the SiC substrate. The polarity inverting layer may be, for instance, the polarity inverting layer 104 described with reference to FIGS. 2 and 5-7. The polarity inverting layer may induce a polarity inversion in the Group III-nitride semiconductor structure during formation of the Group III-nitride semiconductor structure. The polarity inverting layer may be, for instance, a transition metal nitride layer. For instance, the polarity inverting layer may be niobium nitride (NbₓN_{y}), titanium nitride (TiₓN_{y}), zirconium nitride (ZrₓN_{y}), hafnium nitride (HfₓN_{y}), vanadium nitride (VₓN_{y}), tantalum nitride (TaₓN_{y}), chromium nitride (CrₓN_{y}), molybdenum nitride (MoₓN_{y}), or tungsten nitride (WₓN_{y}). The polarity inverting layer may be deposited on the substrate using a deposition process, such a chemical vapor deposition (CVD), physical vapor deposition (PVD), sputter deposition, atomic layer deposition (ALD), or other suitable deposition process.

At 156, the method 150 may include epitaxially forming an N-polar Group III-nitride semiconductor structure on the polarity inverting layer. The N-polar Group III-nitride semiconductor structure may be, for instance, the N-polar Group III-nitride semiconductor structure described with reference to FIGS. 2 and 5-7. The Group III-nitride semiconductor structure may be formed on the polarity inverting layer using, for instance, metal-organic chemical vapor deposition (MOCVD), molecular beam epitaxy (MBE), or hydride vapor phase epitaxy (HVPE). Techniques for epitaxial growth of Group III-nitrides have been described in, for example, U.S. Pat. Nos. 5,210,051, 5,393,993, and 5,523,589, the disclosures of which are incorporated by reference herein.

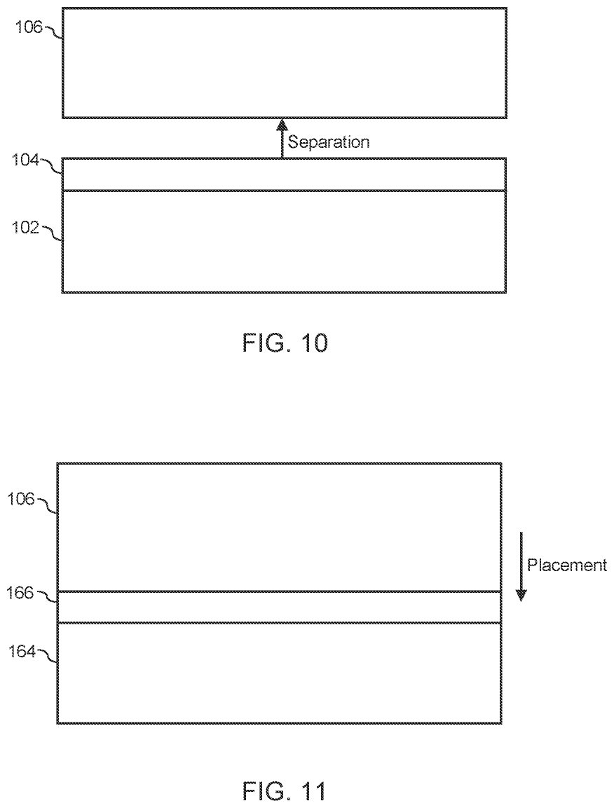

In some examples at 158, the method 150 may additionally include separating the N-polar Group III-nitride semiconductor structure from the substrate, such as the SiC substrate. For instance, as shown in FIG. 10, the N-polar Group III nitride semiconductor structure 106 may be separated from the polarity inverting layer 104 and/or the substrate 102. Any suitable separation process may be used to separate the N-polar Group III nitride semiconductor structure 106 from the polarity inverting layer 104 and/or the substrate 102. For instance, the N-polar Group III nitride semiconductor structure may be removed by inducing a mechanical stress between the N-polar Group III-nitride semiconductor structure 106 and the polarity inverting layer 104 and/or the substrate 102 that causes a separation. As an example, the N-polar Group III-nitride semiconductor structure 106 and/or the substrate 102 may be clamped or otherwise coupled to respective separating structures (e.g., other substrates). Relative motion may be imparted between the separating structures to induce the mechanical stress. For instance, the structure coupled to the N-polar Group III-nitride semiconductor structure 106 may be moved away from the structure coupled to the substrate 102 and/or the structure coupled to the substrate 102 may be moved away from the structure coupled to the Group III-nitride semiconductor structure 106. In some examples, damage may be intentionally induced (e.g., using a laser, ion implantation, etc.) in the polarity inverting layer 104 and/or the substrate 102 to facilitate separation.

Referring to FIG. 9 at 160, in some examples, the method 150 may include placing the Group III-nitride semiconductor structure on a second substrate. The second substrate may be SiC. The second substrate may be a different material, such as a sapphire substrate or a diamond substrate. FIG. 10 depicts the example placement of the N-polar Group III-nitride structure 106 on a second substrate 164. The N-polar Group III-nitride structure 106 may be coupled to the second substrate 164 with or without an adhesive layer 166 or other suitable bonding.

In this way, an N-polar Group III-nitride semiconductor structure may be formed on a substrate, such as a Si-face of a SiC substrate. The N-polar Group III-nitride semiconductor structure may be transferred to a different substrate with or without the transition metal nitride layer for use in a semiconductor device, such as a HEMT device.

Example aspects of the present disclosure are set forth below. Any of the below features or examples may be used in combination with any of the embodiments or features provided in the present disclosure.

One example embodiment of the present disclosure is directed to a semiconductor device. The semiconductor device includes a substrate. The semiconductor device includes a polarity inverting layer on the substrate. The semiconductor device includes a nitrogen-polar (N-Polar) Group III-nitride semiconductor structure on the polarity inverting layer.

In some examples, the substrate comprises a silicon carbide substrate. In some examples, the substrate comprises a 4H-silicon carbide substrate. In some examples, the polarity inverting layer is directly on a silicon face of the silicon carbide substrate.

In some examples, the polarity inverting layer comprises a transition metal nitride. In some examples, the polarity inverting layer has a hexagonal close packed (HCP) crystal structure. In some examples, the polarity inverting layer has a face centered cubic (FCC) crystal structure.

In some examples, the polarity inverting layer has a lattice parameter in a range of about 3.5 Angstroms to about 5 Angstroms. In some examples, the polarity inverting layer has an FCC plane distance in a range of about 2.5 Angstroms to about 3.5 Angstroms. In some examples, the polarity inverting layer has a crystal structure with a percentage lattice mismatch to 4H-silicon carbide of about −6.0% to about 6.0%. In some examples, the polarity inverting layer has a crystal structure with a percentage lattice mismatch to gallium nitride (GaN) of about −10.0% to about 2.0%. In some examples, the polarity inverting layer has a crystal structure with a percentage lattice mismatch to aluminum nitride (AlN) of about −7.0% to about 5.0%.

In some examples, the polarity inverting layer comprises one or more of niobium nitride (NbₓN_{y}), titanium nitride (TiₓN_{y}), zirconium nitride (ZrₓN_{y}), hafnium nitride (HfₓN_{y}), vanadium nitride (VₓN_{y}), tantalum nitride (TaₓN_{y}), chromium nitride (CrₓN_{y}), molybdenum nitride (MoₓN_{y}), or tungsten nitride (WₓN_{y}).

In some examples, the polarity inverting layer has a thickness in a range of about 5 nm to about 100 nm. In some examples, the polarity inverting layer does not exhibit a phase transition in a temperature range of up to about 1300° C.

In some examples, the Group III-nitride semiconductor structure comprises an aluminum nitride layer on the polarity inverting layer. In some examples, the Group III-nitride semiconductor structure comprises a gallium nitride layer on the aluminum nitride layer.

In some examples, the N-polar Group III-nitride semiconductor structure comprises: a barrier layer, wherein the barrier layer comprises N-polar Al_{w}Ga_{1-w}N, where 0.1≤w≤0.4; and a channel layer on the barrier layer, wherein the channel layer comprises N-polar AlₓGa₁₋ₓN, where 0≤x≤0.1.

In some examples, the N-polar Group III-nitride semiconductor structure comprises a buffer layer, wherein the barrier layer is on the buffer layer such that the barrier layer is between the buffer layer and the channel layer. In some examples, the buffer layer comprises N-polar AlᵥGa₁₋ᵥN, where 0≤v≤0.1.

In some examples, the N-polar Group III-nitride semiconductor structure further comprises a nucleation layer, wherein the nucleation layer is between the buffer layer and the polarity inverting layer. In some examples, the nucleation layer comprises N-polar AlᵤGa₁₋ᵤN, where 0.5≤u≤1.

In some examples, the semiconductor device includes one or more cap layers on the channel layer. In some examples, the semiconductor device includes a gate contact, a source contact, and a drain contact on the N-polar Group III-nitride semiconductor structure. In some examples, the semiconductor device is a high electron mobility transistor (HEMT) device. In some examples, the N-polar Group III-nitride structure has a spontaneous polarization dipole in a direction opposite a growth direction of the N-polar Group III-nitride structure.

Another example embodiment of the present disclosure is directed to a transistor device. The transistor device includes a silicon carbide substrate. The transistor device includes a transition metal nitride layer on the silicon carbide substrate. The transistor device includes an N-polar Group III-nitride semiconductor structure on the transition metal nitride layer. The N-polar Group III-nitride semiconductor structure includes a barrier layer and a channel layer on the barrier layer.

In some examples, the silicon carbide substrate is a 4H-silicon carbide substrate. In some examples, the transition metal nitride layer is on a silicon face of the silicon carbide substrate.

In some examples, the transition metal nitride layer has a face centered cubic (FCC) crystal structure or a hexagonal close packed (HCP) crystal structure. In some examples, the transition metal nitride layer has a lattice parameter in a range of about 3.5 Angstroms to about 5 Angstroms. In some examples, the transition metal nitride layer has an FCC plane distance in a range of about 2.5 Angstroms to about 3.5 Angstroms. In some examples, the transition metal nitride layer has a crystal structure with a percentage lattice mismatch to 4H-silicon carbide of about −6.0% to about 6.0%. In some examples, the transition metal nitride layer has a crystal structure with a percentage lattice mismatch to gallium nitride (GaN) of about −10.0% to about 2.0%. In some examples, the transition metal nitride layer has a crystal structure with a percentage lattice mismatch to aluminum nitride (AlN) of about −7.0% to about 5.0%.

In some examples, the transition metal nitride layer comprises one or more of niobium nitride (NbₓN_{y}), titanium nitride (TiₓN_{y}), zirconium nitride (ZrₓN_{y}), hafnium nitride (HfₓN_{y}), vanadium nitride (VₓN_{y}), tantalum nitride (TaₓN_{y}), chromium nitride (CrₓN_{y}), molybdenum nitride (MoₓN_{y}), or tungsten nitride (WₓN_{y}).

In some examples, the transition metal nitride layer has a thickness in a range of about 5 nm to about 100 nm. In some examples, the transition metal nitride layer does not exhibit a phase transition in a temperature range of up to about 1300° C.

In some examples, the barrier layer comprises N-polar Al_{w}Ga_{1-w}N where 0.1≤w≤0.4. In some examples, the channel layer comprises N-polar AlₓGa₁₋ₓN, where 0≤x≤0.1.

In some examples, the N-polar Group III-nitride semiconductor structure comprises a buffer layer, wherein the barrier layer is on the buffer layer such that the barrier layer is between the buffer layer and the channel layer. In some examples, the buffer layer comprises N-polar AlᵥGa₁₋ᵥN, where 0≤v≤0.1.

In some examples, the N-polar Group III-nitride semiconductor structure further comprises a nucleation layer, wherein the nucleation layer is between the buffer layer and the transition metal nitride layer. In some examples, the nucleation layer comprises N-polar AlᵤGa₁₋ᵤN, where 0.5≤u≤1.

In some examples, the N-polar Group III-nitride semiconductor structure comprises one or more cap layers. In some examples, the one or more cap layers comprise a first cap layer and a second cap layer. In some examples, the first cap layer comprises N-polar Al_{y}Ga_{1-y}N, where 0.1≤y≤0.4. In some examples, the second cap layer comprise N-polar Al_{z}Ga_{1-z}N, where 0≤z≤0.1.

In some examples, the transistor device includes a gate contact, a source contact, and a drain contact on the N-polar Group III-nitride semiconductor structure. In some examples, the transistor device is an HEMT device. In some examples, the N-polar Group III-nitride structure has a spontaneous polarization dipole in a direction opposite a growth direction of the N-polar Group III-nitride structure.

Another example embodiment of the present disclosure is directed to a method of forming an N-polar Group III-nitride semiconductor structure. The method includes depositing a polarity inverting layer on a silicon face of a silicon carbide substrate. The method includes epitaxially forming an N-polar Group III-nitride semiconductor structure on the polarity inverting layer.

In some examples, the polarity inverting layer comprises a transition metal nitride. In some examples, the polarity inverting layer has a face centered cubic (FCC) crystal structure or a hexagonal close packed (HCP) crystal structure. In some examples, the polarity inverting layer has a lattice parameter in a range of about 3.5 Angstroms to about 5 Angstroms. In some examples, the polarity inverting layer has an FCC plane distance in a range of about 2.5 Angstroms to about 3.5 Angstroms. In some examples, the polarity inverting layer has a crystal structure with a percentage lattice mismatch to 4H-silicon carbide of about −6.0% to about 6.0%. In some examples, the polarity inverting layer has a crystal structure with a percentage lattice mismatch to gallium nitride (GaN) of about −10.0% to about 2.0%. In some examples, the polarity inverting layer has a crystal structure with a percentage lattice mismatch to aluminum nitride (AlN) of about −7.0% to about 5.0%.

In some examples, the polarity inverting layer comprises one or more of niobium nitride (NbₓN_{y}), titanium nitride (TiₓN_{y}), zirconium nitride (ZrₓN_{y}), hafnium nitride (HfₓN_{y}), vanadium nitride (VₓN_{y}), tantalum nitride (TaₓN_{y}), chromium nitride (CrₓN_{y}), molybdenum nitride (MoₓN_{y}), or tungsten nitride (WₓN_{y}).

In some examples, the polarity inverting layer has a thickness in a range of about 5 nm to about 100 nm. In some examples, the polarity inverting layer does not exhibit a phase transition in a temperature range of up to about 1300° C.

In some examples, the method includes separating the N-polar Group III-nitride semiconductor structure from the silicon carbide substrate. In some examples, the method includes placing the N-polar Group III-nitride semiconductor structure on a second substrate. In some examples, the second substrate includes a diamond substrate or a sapphire substrate.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a substrate;
a polarity inverting layer on the substrate; and
a nitrogen-polar (N-Polar) Group III-nitride semiconductor structure on the polarity inverting layer.

2. The semiconductor device of claim 1, wherein the substrate comprises a silicon carbide substrate.

3. The semiconductor device of claim 2, wherein the substrate comprises a 4H-silicon carbide substrate.

4. The semiconductor device of claim 2, wherein the polarity inverting layer is directly on a silicon face of the silicon carbide substrate.

5. The semiconductor device of claim 2, wherein the polarity inverting layer comprises a transition metal nitride.

6. The semiconductor device of claim 1, wherein the polarity inverting layer has a hexagonal close packed (HCP) crystal structure or a face centered cubic (FCC) crystal structure.

7. (canceled)

8. The semiconductor device of claim 6, wherein the polarity inverting layer has a lattice parameter in a range of about 3.5 Angstroms to about 5 Angstroms.

9. The semiconductor device of claim 6, wherein the polarity inverting layer has an FCC plane distance in a range of about 2.5 Angstroms to about 3.5 Angstroms.

10. The semiconductor device of claim 1, wherein the polarity inverting layer has a crystal structure with a percentage lattice mismatch to 4H-silicon carbide of about −6.0% to about 6.0%.

11. The semiconductor device of claim 1, wherein the polarity inverting layer has a crystal structure with a percentage lattice mismatch to gallium nitride (GaN) of about −10.0% to about 2.0%.

12. The semiconductor device of claim 1, wherein the polarity inverting layer has a crystal structure with a percentage lattice mismatch to aluminum nitride (AlN) of about −7.0% to about 5.0%.

13. The semiconductor device of claim 1, wherein the polarity inverting layer comprises one or more of niobium nitride (NbₓN_{y}), titanium nitride (TiₓN_{y}), zirconium nitride (ZrₓN_{y}), hafnium nitride (HfₓN_{y}), vanadium nitride (VₓN_{y}), tantalum nitride (TaₓN_{y}), chromium nitride (CrₓN_{y}), molybdenum nitride (MoₓN_{y}), or tungsten nitride (WₓN_{y}).

14. The semiconductor device of claim 1, wherein the polarity inverting layer has a thickness in a range of about 5 nm to about 100 nm.

15. The semiconductor device of claim 1, wherein the polarity inverting layer does not exhibit a phase transition in a temperature range of up to about 1300° C.

16.-24. (canceled)

25. The semiconductor device of claim 1, wherein the semiconductor device is a high electron mobility transistor (HEMT) device.

26. The semiconductor device of claim 1, wherein the N-polar Group III-nitride structure has a spontaneous polarization dipole in a direction opposite a growth direction of the N-polar Group III-nitride structure.

27. A transistor device, comprising:
a silicon carbide substrate;
a transition metal nitride layer on the silicon carbide substrate; and
a nitrogen-polar (N-polar) Group III-nitride semiconductor structure on the transition metal nitride layer, the N-polar Group III-nitride semiconductor structure comprising a barrier layer and a channel layer on the barrier layer.

28.-38. (canceled)

39. The transistor device of claim 27, wherein the barrier layer comprises N-polar AlwGa1−wN where 0.1≤w≤0.4, wherein the channel layer comprises N-polar AlxGa1−xN, where 0≤x≤0.1.

40.-44. (canceled)

45. The transistor device of claim 27, wherein the N-polar Group III-nitride semiconductor structure comprises one or more cap layers, wherein the one or more cap layers comprise a first cap layer and a second cap layer, wherein the first cap layer comprises N-polar AlyGa1−yN, where 0.1≤y≤0.4, wherein the second cap layer comprise N-polar AlzGa1−zN, where 0≤z≤0.1.

46.-51. (canceled)

52. A method of forming a nitrogen-polar (N-polar) Group III-nitride semiconductor structure, comprising:
depositing a polarity inverting layer on a silicon face of a silicon carbide substrate; and
epitaxially forming an N-polar Group III-nitride semiconductor structure on the polarity inverting layer.

53.-65. (canceled)
